(19) United States
(12) Patent Application Publication
(10) Pub. No.: US 2002/0064948 A1
(43) Pub. Date: May 30, 2002

(54) Preparation method of bis (alkylcyclopentadienyl) ruthenium

(75) Inventors: Masayuki Saito, Kanagawa (JP); Jun-ichi Taniuchi, Kanagawa (JP)

Correspondence Address: ARENT FOX KINTNER PLOTKIN & KAHN, PLLC, 1050 Connecticut Avenue, N.W., Suite 600, Washington, DC, 20036-5339, US

(73) Assignee: Tanaka Kikinzoku Kogyo K.K. (Japanese Corporatin)

(21) Appl. No.: 09/804,185

(22) Filed: Mar. 13, 2001

(30) Foreign Application Priority Data
Nov. 8, 2000 (JP) 2000-340151

(51) Int. Cl. H01L 21/443; C07F 15/00; C23C 16/18

(52) U.S. Cl. 438/681; 438/686; 556/136

(57) ABSTRACT

The present invention is a preparation method of the bis(alkylcyclopentadienyl)ruthenium by reacting a ruthenium compound, an alkylcyclopentadiene and a reducing agent, wherein the ruthenium compound, the alkylcyclopentadiene, and the reducing agent are reacted in the presence of a base. It is preferable that at least one of ammonia, amines, ammonium compounds, hydroxides, aniline, nitroaniline, aminophenol, aminodiphenyl, piperidine, Grignard reagents, alkali metals, alkoxides, phenyl lithium, methyl lithium, n-butyryl lithium, lithium aluminium hydride, and sodium amide is added as a base to the reaction system and the ruthenium compound, the alkylcyclopentadiene, and the reducing agent are reacted.

### BACKGROUND OF THE INVENTION

1. Field of the Invention

The present invention relates to a preparation method of the bis(alkylcyclopentadienyl)ruthenium which is an organometallic compound used for forming ruthenium thin films or thin films of ruthenium compounds by the chemical vapor deposition method.

2. Description of the Prior Art

Semiconductor devices are continuously required to have higher performance and researches on DRAMs (dynamic RAM) are made in an attempt to increase its capacity from M-bit order to G-bit order. With this trend, the technology for production of semiconductor devices with higher degree of density and integration is rapidly progressing and improvement in structure as well as in materials used for the devices is made for an increase in capacity.

Under these situations, attention is directed to precious metals or precious metal compounds, especially ruthenium or ruthenium compounds as a material for film electrodes for semiconductor devices. This is because these materials have low resistivity and superior electric characteristics as an electrode and are considered to be a major material for film electrodes in the future. It is examined whether or not these materials can be used as a material for storage electrodes of capacitors for DRAMs and these materials are expected to greatly contribute to higher density.

The chemical vapor deposition method (hereinafter referred to as CVD method) is generally employed as a method to prepare a ruthenium thin film or a thin film of ruthenium compounds. The CVD method has the advantages that it can easily prepare uniform thin films and it is superior in step coverage. The CVD method is considered to be a major process for preparation of film electrodes in the future, which can provide further densification for recent circuits and electronic parts.

As a raw material for the ruthenium film and thin films of ruthenium compounds by the CVD method, use of the bis(alkylcyclopentadienyl)ruthenium is being examined, which is obtained by substituting alkyl groups such as ethyl group and propyl group for protons on the two cyclopentadiene rings of bis(cyclopentadienyl)ruthenium (trivial name: ruthenocene) represented by the following formula.

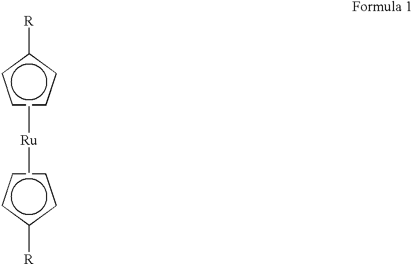

(in the general formula the substituent R is a linear or branched alkyl group)

As a preparation method of the bis(alkylcyclopentadienyl)ruthenium, a method is known in which an alkylcyclopentadiene represented by Formula 2 is reacted with ruthenium chloride represented by Formula 3 and zinc powder in an alcohol solvent. For example, Japanese Patent Application Laid-open (Kokai) No.11-35589 discloses a preparation method of bis(ethylcyclopentadienyl)ruthenium and bis(isopropylcyclopentadienyl)ruthenium according to the method. The method involves dissolving ruthenium chloride in an alcohol solvent, mixing ethylcyclopentadiene (isopropylcyclopentadiene) and adding powder zinc of high purity.

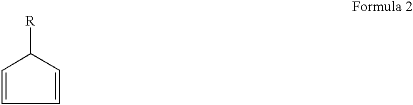

(in the general formula the substituent R has the meaning as defined above)

RuCl₃ Formula 3

The reaction in which the bis(alkylcyclopentadienyl)ruthenium is formed according to this conventional preparation method includes reduction of trivalent ruthenium ion, which has been dissociated from a ruthenium compound, with a reducing agent and simultaneous reaction of divalent ruthenium ion, which has been reduced, with an alkylcyclopentadiene.

Furthermore, the above-mentioned prior art describes the temperature in the reaction system is preferably maintained in the range of −30° C. to 0° C. This is because the above-mentioned formation reaction of a series of the bis(alkylcyclopentadienyl)ruthenium is an exothermal reaction accompanied by rapid evolution of heat, and therefore the temperature in the reaction system is increased, which leads to polymerization of the alkylcyclopentadiene resulting in solid matter as impurities. In this connection, the reaction is preferably conducted in the range of −30° C. to 0° C., especially in the range of −30° C. to −10° C. in order to improve the purity of desired bis(alkylcyclopentadienyl)ruthenium and ensure its yield.

Furthermore, in the above-mentioned conventional method, zinc acts as a reducing agent which reduces trivalent ruthenium ion to divalent ruthenium ion and it is necessary to add the reducing agent in portions to the reaction system. This is because the bis(alkylcyclopentadienyl)ruthenium forms upon contact between ruthenium chloride, ethylcyclopentadiene (isopropylcyclopentadiene), and zinc, and, if the required amount of zinc is added in one portion, the formation reaction rapidly proceeds and overheats the reaction system. In this connection, zinc is required to add in portions in order to maintain the reaction system in the range of −30° C. to 0° C.

However, it is not easy to maintain the reaction system at low temperatures below 0° C. In particular, a large-scale cooling unit and a large quantity of utility such as liquid nitrogen are necessary for mass production, which boosts equipment costs and running costs, leading to an increase in production costs of the bis (alkylcyclopentadienyl) ruthenium. This phenomenon of increased costs will further expand in view of an increase of demand for ruthenium film electrodes and an increase of demand for the bis(alkylcyclopentadienyl)ruthenium in the future.

Although the separate addition of zinc is necessary in order to control the reaction temperature, since the bis(alkylcyclopentadienyl)ruthenium is formed in an amount corresponding to the amount of zinc added, significant amounts of unreacted ruthenium chloride and alkylcyclopentadiene remain in contact in the initial stage of the reaction. Under the situation where unreacted ruthenium chloride make contact with the alkylcyclopentadiene, side reactions may occur, although they are minor, and impurities other than polymers of the alkylcyclopentadiene may be formed.

Furthermore, the separate addition of the reducing agent has a problem that even a slightly mishandled separate addition may overheat the reaction system and polymerize the alkylcyclopentadiene. Therefore, the amount to be added should be regulated but it must be changed according to the intended amount of the bis(alkylcyclopentadienyl)ruthenium, i.e., the amount of each raw material compound. It is not necessarily easy to change the amount of the reducing agent to be added for each preparation condition and such changes for each condition prohibit a flexible response to the production and reduces production efficiency.

The present invention has been made in view of the situations described above and is directed to provide a method for preparing the bis(alkylcyclopentadienyl)ruthenium by reacting a ruthenium compound, an alkylcyclopentadiene, and a reducing agent wherein the bis(alkylcyclopentadienyl)ruthenium of high purity can be obtained without cooling the reaction system and the separate addition of the reducing agent.

### SUMMARY OF THE INVENTION

The reaction in the conventional preparation method of the bis(alkylcyclopentadienyl)ruthenium is a direct reaction between ruthenium ion and an alkylcyclopentadiene and the overheating of the reaction system is attributed to the heat of reaction generated by the direct reaction. In this connection, the inventors have intensively investigated and, as a result, found that the above-mentioned problem can be solved by forming an intermediate step where an alkylcyclopentadiene is deprotonated to form an alkylcyclopentadiene anion and then reacting the alkylcyclopentadiene anion and ruthenium ion. This is based on the consideration that a deprotonated alkylcyclopentadiene anion and divalent ruthenium ion readily react to form a bis(alkylcyclopentadienyl)ruthenium without rapid evolution of heat.

The inventors have conceived the present invention based on an idea it is appropriate to render a base present in the reaction system in order to deprotonate an alkylcyclopentadiene for forming these stepwise reactions.

Accordingly, the present invention is directed to a preparation method of the bis(alkylcyclopentadienyl)ruthenium represented by Formula 5 by reacting a ruthenium compound, an alkylcyclopentadiene represented by Formula 4, and a reducing agent, wherein the ruthenium compound, the alkylcyclopentadiene, and the reducing agent are reacted in the presence of a base:

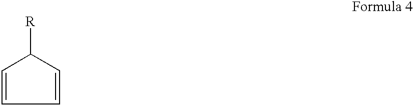

(in the general formula the substituent R is a linear or branched alkyl group)

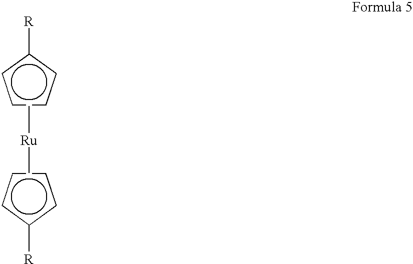

(in the general formula the substituent R has the meaning as defined above).

The term base used herein is intended to mean a proton acceptor defined by the proton theory by Brønsted, i.e., a molecule or ion having a tendency to accept a hydrogen ion from other compounds containing a hydrogen atom (proton). Compounds which act as a base toward the alkylcyclopentadiene in the present invention include amines (primary amines, secondary amines, and tertiary amines), ammonium compounds, and hydroxides and specific examples include ammonia, diethylamine, trimethylamine, potassium hydroxide, and sodium hydroxide. In addition, aniline, nitroaniline, aminophenol, aminodiphenyl, piperidine, Grignard reagents, alkali metals such as sodium, alkoxides, and alkali metal compounds such as phenyl lithium, methyl lithium, n-butyryl lithium, lithium aluminium hydride, and sodium amide can work as a base. Incidentally, these bases can be added to the reaction system before or concurrent with the time when a ruthenium compound, an alkylcyclopentadiene, and a reducing agent are reacted. If the base is added to the reaction system after the ruthenium compound, the alkylcyclopentadiene, and the reducing agent are reacted, it cannot avoid the overheating in the reaction system because the formation reaction of the bis(alkylcyclopentadienyl)ruthenium has already started. Therefore, these compounds and the base may be mixed simultaneously, or the ruthenium compound, the alkylcyclopentadiene, and the base are mixed and the reducing agent then may be added.

As the reducing agent, although zinc, which is used in the prior art, is applicable, a wide variety of reducing agents are also applicable such as hydrogen, alkali metals, alkali earth metals, transition metals, platinum metals, sodium boron hydride, dimethylamineborane, trimethylamineborane, hydrazine, hydrazine hydrochloride, cuprous chloride, cuprous iodide, calcium hydride, lithium aluminium hydride, alcohols, formalin, and formic acid. For example, as the alkali metals, lithium, sodium, and potassium are applicable, and as the alkali earth metals, magnesium, calcium, and barium are applicable. As the transition metals, titanium, vanadium, chromium, manganese, iron, cobalt, nickel, copper, strontium, zirconium, niobium, and molybdenum are usable. Furthermore, silver, gold, platinum, rhodium, iridium, ruthenium, and palladium are applicable.

Although no limitation is set as to the ruthenium compounds for use as a raw material in the present invention, ruthenium chloride, ruthenium nitrate, ruthenium sulfate, and ruthenium acetate are preferably used in terms of availability.

In the preparation method of the bis(alkylcyclopentadienyl)ruthenium according to the present invention, it is preferable that the reaction is conducted in a suitable solvent containing the compounds. As the solvent, alcohols, especially ethyl alcohol is preferably used.

According to the present invention, the bis(alkylcyclopentadienyl)ruthenium can be easily formed without rapid evolution of heat. Therefore, it is not necessary to maintain the reaction system at low temperatures to avoid formation of impurities (alkylcyclopentadiene polymers) due to the overheating of the reaction system as in the conventional method. Consequently, according to the present invention, the bis(alkylcyclopentadienyl)ruthenium can be formed at room temperature. As a result, the bis(alkylcyclopentadienyl)ruthenium can be produced without using a large-scale cooling unit and, especially in the case of mass-production, production facilities can be simplified and ancillary facilities can be omitted, which reduces production costs.

Moreover, the required amount of the above-mentioned reducing agent may be added in one portion without separate addition in the present invention. The heat of reaction of the formation reaction of the bis(alkylcyclopentadienyl)ruthenium according to the present invention is low and the reaction system cannot be overheated regardless of the amount of the reducing agent. Therefore, it is needless to consider the amount of the reducing agent to be divided in portions for each production condition in the present invention, thereby providing a good production efficiency. Furthermore, since the reducing agent may be added in one portion in the present invention, the side reaction, which is observed in the conventional method, due to contact between unreacted ruthenium chloride and an alkylcyclopentadiene is inhibited, which allows the bis(alkylcyclopentadienyl)ruthenium of high purity to be prepared.

### EMBODIMENT OF THE INVENTION

A suitable embodiment of the present invention is described hereinafter. In the embodiment, bis(ethylcyclopentadienyl)ruthenium was formed as a bis(alkylcyclopentadienyl)ruthenium and its purity was analyzed and a ruthenium thin film was prepared using the bis(ethylcyclopentadienyl)ruthenium and the properties of the thin film was evaluated.

Into a nitrogen-purged flask, 70 ml of ethyl alcohol as a solvent, 2.6 g of ruthenium chloride trihydrate as well as 9.1 g of diethylamine as a base and 1.2 g of dimethylamineborane as a reducing agent were placed and reacted. The reaction was carried out at room temperature (25° C.) for 24 hours. The reaction was conducted under a nitrogen stream.

After the reaction, 30 ml of 3N hydrochloric acid was added to the reaction liquid to neutralize and wash and bis(ethylcyclopentadienyl)ruthenium was extracted with hexane, which was removed from the extracting solvent to obtain 1.7 g of bis(ethylcyclopentadienyl)ruthenium.

Analysis of bis(ethylcyclopentadienyl)ruthenium thus prepared by gas chromatography gave a profile with a predominant peak assignable to bis(ethylcyclopentadienyl)ruthenium with few peaks assignable to impurities. The purity was found to be 99%, which is an extremely high figure.

A ruthenium thin film was prepared with bis(ethylcyclopentadienyl)ruthenium prepared in the embodiment by the CVD method. The reaction conditions employed are as follows:

Substrate temperature: 300° C.

Chamber pressure: 700 Pa (5 Toor)

Carrier gas: argon/air

Carrier gas flow: 200/200 sccm

The surface of the ruthenium thin film prepared according to the conditions above was subjected to surface analysis by an AFM (Atomic Force Microscope) to observe the morphology of the thin film and measure the roughness of the film surface. As a result, the average surface roughness (Rₘₛ) was found to be 1.5 nm, which is a good value, and the morphology was found to be good.

### COMPARATIVE EXAMPLE 1

Bis(ethylcyclopentadienyl)ruthenium was prepared according to the conventional reactions in order to ensure the purity of bis(ethylcyclopentadienyl)ruthenium prepared in the embodiment.

Into a nitrogen-purged flask, 200 ml of ethyl alcohol as an alcohol solvent, 25.0 g of ruthenium chloride trihydrate were placed and dissolved. The mixture was cooled to −30° C. and 40 g of ethylcyclopentadiene was added. As the reaction liquid was maintained at −25 to −10° C. and stirred, 9.55 g of powder zinc was added in seven portions and the solution was maintained at 10° C. for 20 minutes.

After the reaction, bis(ethylcyclopentadienyl)ruthenium was extracted with hexane, which was removed from the extracting solvent to obtain 19.7 g of bis(ethylcyclopentadienyl)ruthenium.

Analysis of bis(ethylcyclopentadienyl)ruthenium according to Comparative Example 1 by gas chromatography revealed the purity was 94%.

### COMPARATIVE EXAMPLE 2

As the second comparative example, the preparation procedures of bis(ethylcyclopentadienyl)ruthenium according to Comparative Example 1 was repeated with the exception that zinc powder was added in one portion. The same amount of each reagent and the same conditions as Comparative Example 1 were employed.

When zinc was added in one portion, the reaction proceeded with intense evolution of heat and only solid polymers were left in the reaction liquid after the reaction. It is considered the polymers were formed by polymerization of ethylcyclopentadiene due to the heat of reaction caused by collective addition of zinc.

1. A preparation method of the bis(alkylcyclopentadienyl)ruthenium represented by Formula 7 by reacting a ruthenium compound, an alkylcyclopentadiene represented by Formula 6, and a reducing agent, wherein the ruthenium compound, the alkylcyclopentadiene, and the reducing agent are reacted in the presence of a base: 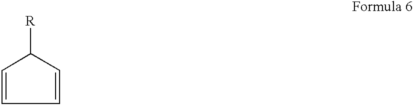
(in the general formula the substituent R is a linear or branched alkyl group) 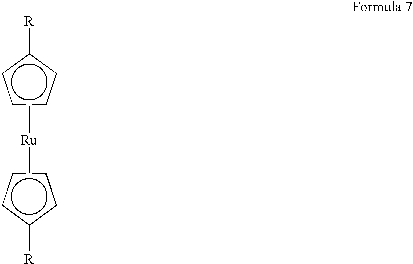
(in the general formula the substituent R has the meaning as defined above).

2. The preparation method of the bis(alkylcyclopentadienyl)ruthenium according to claim 1, wherein at least one of: ammonia, amines, ammonium compounds, hydroxides, aniline, nitroaniline, aminophenol, aminodiphenyl, piperidine, Grignard reagents, alkali metals, alkoxides, phenyl lithium, methyl lithium, n-butyryl lithium, lithium aluminium hydride, and sodium amide is added as a base to the reaction system, and the ruthenium compound, the alkylcyclopentadiene, and the reducing agent are reacted.

3. The preparation method of the bis(alkylcyclopentadienyl)ruthenium according to claim 1, wherein at least one of: hydrogen, alkali metals, alkali earth metals, transition metals, precious metals, sodium boron hydride, dimethylamineborane, trimethylamineborane, hydrazine, hydrazine hydrochloride, cuprous chloride, cuprous iodide, calcium hydride, lithium aluminium hydride, alcohols, formalin, and formic acid is reacted as a reducing agent.

4. The preparation method of the bis(alkylcyclopentadienyl)ruthenium according to claim 2, wherein at least one of: hydrogen, alkali metals, alkali earth metals, transition metals, precious metals, sodium boron hydride, dimethylamineborane, trimethylamineborane, hydrazine, hydrazine hydrochloride, cuprous chloride, cuprous iodide, calcium hydride, lithium aluminium hydride, alcohols, formalin, and formic acid is reacted as a reducing agent.

5. The preparation method of the bis(alkylcyclopentadienyl)ruthenium according to claim 1, wherein ruthenium chloride, ruthenium nitrate, ruthenium sulfate, or ruthenium acetate is reacted as a ruthenium compound.

6. The preparation method of the bis(alkylcyclopentadienyl)ruthenium according to claim 2, wherein ruthenium chloride, ruthenium nitrate, ruthenium sulfate, or ruthenium acetate is reacted as a ruthenium compound.

7. The preparation method of the bis(alkylcyclopentadienyl)ruthenium according to claim 3, wherein ruthenium chloride, ruthenium nitrate, ruthenium sulfate, or ruthenium acetate is reacted as a ruthenium compound.

8. The preparation method of the bis(alkylcyclopentadienyl)ruthenium according to claim 4, wherein ruthenium chloride, ruthenium nitrate, ruthenium sulfate, or ruthenium acetate is reacted as a ruthenium compound.

9. The bis(alkylcyclopentadienyl)ruthenium prepared by the method according to claim 1.

10. The bis(alkylcyclopentadienyl)ruthenium prepared by the method according to claim 2.

11. The bis(alkylcyclopentadienyl)ruthenium prepared by the method according to claim 3.

12. The bis(alkylcyclopentadienyl)ruthenium prepared by the method according to claim 4.

13. The bis(alkylcyclopentadienyl)ruthenium prepared by the method according to claim 5.

14. The bis(alkylcyclopentadienyl)ruthenium prepared by the method according to claim 6.

15. The bis(alkylcyclopentadienyl)ruthenium prepared by the method according to claim 7.

16. The bis(alkylcyclopentadienyl)ruthenium prepared by the method according to claim 8.

17. A preparation method of a ruthenium thin film or a thin film of a ruthenium compound from the bis(alkylcyclopentadienyl)ruthenium prepared by the method according to claim 1 by CVD method.

18. A preparation method of a ruthenium thin film or a thin film of a ruthenium compound from the bis(alkylcyclopentadienyl)ruthenium prepared by the method according to claim 2 by CVD method.

19. A preparation method of a ruthenium thin film or a thin film of a ruthenium compound from the bis(alkylcyclopentadienyl)ruthenium prepared by the method according to claim 3 by CVD method.

20. A preparation method of a ruthenium thin film or a thin film of a ruthenium compound from the bis(alkylcyclopentadienyl)ruthenium prepared by the method according to claim 4 by CVD method.

21. A preparation method of a ruthenium thin film or a thin film of a ruthenium compound from the bis(alkylcyclopentadienyl)ruthenium prepared by the method according to claim 5 by CVD method.

22. A preparation method of a ruthenium thin film or a thin film of a ruthenium compound from the bis(alkylcyclopentadienyl)ruthenium prepared by the method according to claim 6 by CVD method.

23. A preparation method of a ruthenium thin film or a thin film of a ruthenium compound from the bis(alkylcyclopentadienyl)ruthenium prepared by the method according to claim 7 by CVD method.

24. A preparation method of a ruthenium thin film or a thin film of a ruthenium compound from the bis(alkylcyclopentadienyl)ruthenium prepared by the method according to claim 8 by CVD method.
